(19) United States
(12) Patent Application Publication
(10) Pub. No.: US 2006/0130999 A1
(43) Pub. Date: Jun. 22, 2006

(54) Heat exchanger with interchangeable fan assemblies

(76) Inventor: Doug Kennon, Owatonna, MN (US)

Correspondence Address: AMSTED Industries Incorporated;Two Prundential Plaza, 180 North Stetson Street, Suite 1800, Chicago, IL, 60601, US

(21) Appl. No.: 10/713,920

(22) Filed: Mar. 17, 2003

(51) Int. Cl. H01L 23/467

(52) U.S. Cl. 165/76; 165/121

(57) ABSTRACT

A heat exchanger is provided having a plurality of coil circuits. Each coil circuit extends from an inlet header to an outlet header. The structure supporting the coils has an inlet face and an outlet face. A fan assembly draws air in the inlet face and out the outlet face. The fan assembly can be readily attached and detached from the inlet face.

### BACKGROUND OF THE INVENTION

The present invention relates to heat exchangers, and, more particularly, to coil heat exchangers having interchangeable fan assemblies.

Typical coil heat exchangers are comprised of a coil assembly of a series of elongated coil tubes with one end connected to an inlet header and the other end connected to an outlet header. Such coil assembly can be formed in an elongated, generally rectangular array housed in an elongated, generally rectangular structure. Such structure is usually formed of sheet metal with appropriate supports. Air is blown or drawn across the coil assembly by fans integrally mounted in one side of the coil assembly. It is difficult to access the coil assembly due to the presence of such integral fans. It is also difficult to change out the fans in the event of a need to replace them.

### SUMMARY OF THE INVENTION

The present invention provides a coil heat exchanger with a coil assembly of a series of elongated coil tubes mounted in an elongated, generally rectangular structure. Fans for blowing or drawing air across the coil assembly are provided as modular units that are mounted to the structure. Such fans can be readily removed in the event of a need to access the coil assembly or to replace the fans.

### BRIEF DESCRIPTION OF THE DRAWINGS

In the drawings,

FIG. 1 is a perspective view of a coil heat exchanger in accordance with the present invention,

FIG. 2 is a perspective, exploded view of a coil heat exchanger in accordance with the present invention.

### DETAILED DESCRIPTION OF PREFERRED EMBODIMENTS

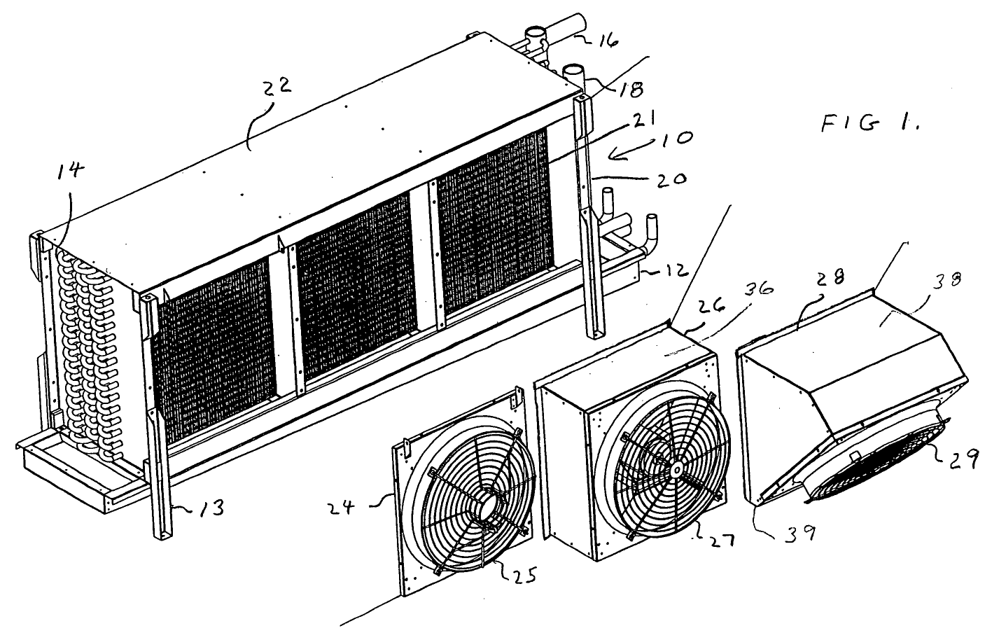

Referring now to FIG. 1, a coil heat exchanger 10 is shown as an elongated, generally rectangular structure. An elongated, generally rectangular base pan 12 is provided and is usually comprised of sheet metal. A plurality of coil circuits 14 is provided, with each coil circuit 14 usually comprised of metal tubing. Inlet header 16 and outlet header 18 are connected to opposite ends coil circuit 14 to enable a working fluid, such as water or a glycol based fluid, to be circulated through coil circuit 14.

An elongated, generally rectangular structure 20 is provided to house coil circuit 14. Structure 14 is usually comprised of sheet metal, with structural legs 13 being affixed near the bottom of structure 14 to support it.

A roof section 22 covers the top of structure 20; roof section 22 again is usually comprised of sheet metal.

Air inlet sections 21 are formed along one side of structure 20, with it being understood that similar air outlet sections are formed on the opposite side of structure 20.

Modular fan assembly 24 is a generally square structure, usually of sheet metal, that includes flush mounted fan 25. Modular fan assembly 26 is a generally square structure, usually of sheet metal, that includes an extended mounted fan 27. Modular fan assembly 28 is a generally square structure, usually of sheet metal, that includes an angle mounted fan 29. Any one of modular fan assemblies 24, 26, or 28 can be affixed to one of air inlet openings 21 on the side of structure 20. Such affixing is usually by the use of sheet metal screws through corresponding openings in an edge of modular fan assembly 24, 26, or 28 and the side of structure 20. The use of such a mounting arrangement allows the ready removal of any of modular fan assemblies 24, 26, or 28 for access to coil circuit 14 or the replacement of a fan assembly. It should be understood that the direction of fan rotation can be selected so that air inlet side 21 could alternately be the air outlet side.

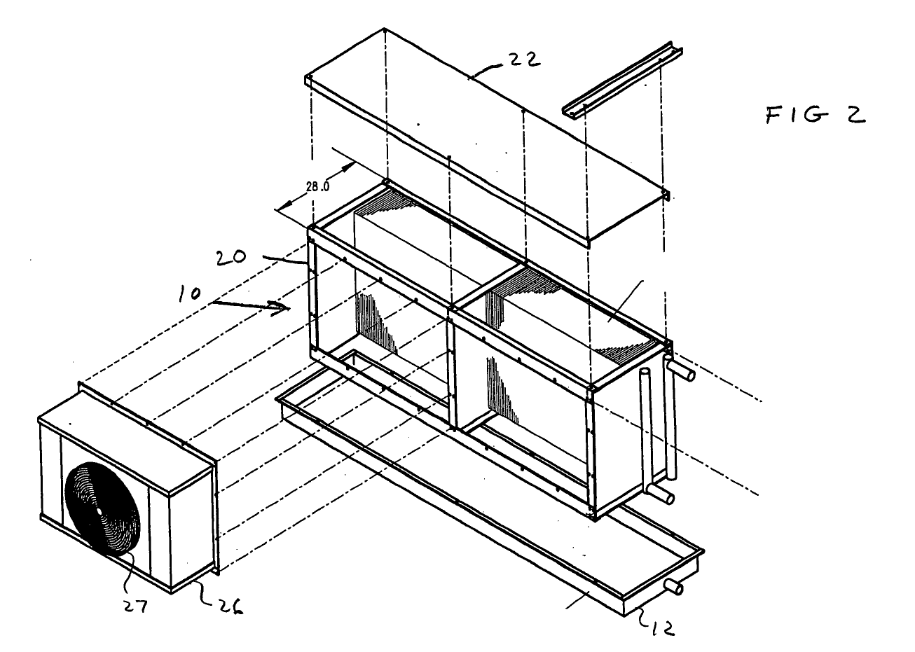

Referring now to FIG. 2, an exploded view of coil heat exchanger 10 is shown with the various components of structure 20. These components include base pan 12, roof 22 and modular fan assembly 26.

What is claimed is:

1. A heat exchanger comprising
a plurality of coil circuits each extending from an inlet header to an outlet header, each coil circuit comprised of elongated tubing,
a structure supporting the coil circuits, the structure having an inlet face and an outlet face,
a fan assembly mounted adjacent the inlet face such that air can be drawn by the fan assembly with the inlet face, across the coil circuit and out the outlet face,
wherein the fan assembly can be readily attached and detached from the inlet face.

2. The heat exchanger of claim 1
wherein the structure includes a top portion, bottom portion and a plurality of vertical supports extending vertically between the top portion and the bottom portion,
and the fan assembly is attached to the top portion, bottom portion and at least one vertical support.

3. The heat exchanger of claim 2
wherein the fan assembly comprises a base support and a fan, with the fan mounted on the base support such that the base support has a generally flat edge,
the flat edge of the base support being positioned adjacent and attached to the top portion, bottom portion and at least one vertical support of the structure.

4. The heat exchanger of claim 3
wherein the fan assembly includes an extending section between the flat edge of the base support and the fan such-that the fan is spaced from the flat edge,
and wherein the extending section is formed of a solid material.

5. The heat exchanger of claim 4
wherein the extending section is formed of sheet metal.

6. The heat exchanger of claim 4
wherein the extending section is of uniform dimension such that the fan is mounted in a plane perpendicular to the inlet face.

7. The heat exchanger of claim 4
wherein the extending section includes a top section and a bottom section, and the top section is of a length greater than the length of the bottom section such that the fan is wanted at an angle to the inlet face.

8. A heat exchanger comprising
a plurality of coil circuits each extending from an inlet header to an outlet header, each coil circuit comprised of elongated tubing,
a structure supporting the coil circuits, the structure having an inlet face and an outlet face,
a fan assembly mounted adjacent the outlet face such that air can be drawn by the fan assembly with the inlet face, across the coil circuit and out the outlet face,
wherein the fan assembly can be readily attached and detached from the inlet face.

9. The heat exchanger of claim 8
wherein the structure includes a top portion, bottom portion and a plurality of vertical supports extending vertically between the top portion and the bottom portion,
and the fan assembly is attached to the top portion, bottom portion and at least one vertical support.

10. The heat exchanger of claim 9
wherein the fan assembly comprises a base support and a fan, with the fan mounted on the base support such that the base support has a generally flat edge,
the flat edge of the base support being positioned adjacent and attached to the top portion, bottom portion and at least one vertical support of the structure.

11. The heat exchanger of claim 10
wherein the fan assembly includes an extending section between the flat e [symbol] the base support and the fan such that the fan is spaced from the flat edge,
and wherein the extending section is formed of a solid material.

12. The heat exchanger of claim 11
wherein the extending section is formed of sheet metal.

13. The heat exchanger of claim 11
wherein the extending section is of uniform dimension such that the fan is mounted in a plane perpendicular to the outlet face.

14. The heat exchanger of claim 4
wherein the extending section includes a top section and a bottom section, and the top section is of a length greater than the length of the bottom section such that the fan is mounted at an angle to the outlet face.
